(19) United States
(12) Patent Application Publication
(10) Pub. No.: US 2025/0263839 A1
(43) Pub. Date: Aug. 21, 2025

(54) METHODS AND SYSTEMS FOR DEPOSITING METALLOID LAYER

(71) Applicant: ASM IP Holding B.V., Almere (NL)

(72) Inventors: Timo Hatanpää, Espoo (FI); Mikko Ritala, Espoo (FI); Paavo Porri, Helsinki (FI)

(21) Appl. No.: 19/051,266

(22) Filed: Feb. 12, 2025

Related U.S. Application Data
(60) Provisional application No. 63/553,692, filed on Feb. 15, 2024.

(51) Int. Cl. C23C 16/455; C23C 16/08; C23C 16/18

(52) U.S. Cl. CPC C23C 16/455; C23C 16/08; C23C 16/18

(57) ABSTRACT

The present disclosure relates to methods and apparatuses for depositing metalloid material on a substrate by a cyclic deposition process. The method comprises providing a substrate in a reaction chamber, providing a first precursor into the reaction chamber in a vapor phase; and providing a second precursor into the reaction chamber in a vapor phase to form metalloid material on the substrate. At least one of the first or second precursor comprises a metalloid compound.

### CROSS-REFERENCE TO RELATED APPLICATIONS

This application claims priority to and benefit of U.S. Provisional Application No. 63/553,692, filed Feb. 15, 2024, the entirety of which is incorporated by reference herein.

### PARTIES OF JOINT RESEARCH AGREEMENT

The invention claimed herein was made by, or on behalf of, and/or in connection with a joint research agreement between University of Helsinki and ASM Microchemistry Oy. The agreement was in effect on and before the date the claimed invention was made, and the claimed invention was made as a result of activities undertaken within the scope of the agreement.

### FIELD OF INVENTION

The present disclosure relates to methods and apparatuses for the manufacture of semiconductor devices. More particularly, the disclosure relates to methods and apparatuses for depositing metalloid material on a substrate by a cyclical deposition process, and layers comprising metalloid material.

### BACKGROUND OF THE DISCLOSURE

The global demand for computing power and data storage capabilities is increasing rapidly. Research efforts in academia and in the semiconductor industry have been made to increase transistor density and lower the power consumption of devices. This has led to highly complex structures and the ever-increasing miniaturization of device features. Phase change memory (PCM) materials are considered as strong contenders to form the base for new memory technologies.

Ternary compounds of Ge—Sb—Te (GST) are regarded as the most promising candidates for industrial use. GeTe is also a PCM material with potential uses in, for example, automotive applications. A key aspect of GST and GeTe material development is tuning the stoichiometry, as changes in material composition affect the devices' data retention time, switching speed and other crucial properties. Due to the self-limiting nature of the ALD processes, the stoichiometry tuning must be primarily done by varying the ALD cycling scheme. Therefore, adding tellurium (Te) cycles to the overall process can be used to tune the tellurium concentration of the material.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

Various embodiments of the present disclosure relate to methods of depositing metalloid material on a substrate, to metalloid layer, to a semiconductor device and structure containing said layer, and to deposition assemblies for depositing metalloid material on a substrate.

In a first aspect, a method for deposing metalloid-containing material on a substrate by a cyclic deposition process is disclosed. The method comprises providing a substrate in a reaction chamber; providing a first precursor into the reaction chamber is vapor phase; and providing a second precursor into the reaction chamber in vapor phase. In the method, at least one of the first precursor or the second precursor comprises a metalloid compound.

In some embodiments, the first precursor comprises alkyl silyl or silyl.

In some embodiments, the first precursor comprises metalloid alkyl silyl or metalloid silyl.

In some embodiments, the alkyl is a C1-C4 alkyl.

In some embodiments, the alkyl is ethyl.

In some embodiments, the second precursor comprises a halide.

In some embodiments, the second precursor comprises a metalloid halide.

In some embodiments, the halide is selected from the group consisting of chlorine,

bromine, fluorine and iodine.

In some embodiments, the metalloid is selected from the group consisting of tellurium, germanium, boron, silicon, arsenic, selenium and antimony.

In some embodiments, the metalloid is tellurium or germanium.

In some embodiments, the metalloid in at least one of the first precursor or the second precursor is tellurium.

In some embodiments, the metalloid in the first precursor and the second precursor is tellurium.

In some embodiments, the metalloid in the first precursor is tellurium and the metalloid in the second precursor is germanium.

In some embodiments, the first precursor is selected from the group consisting of (Et₃Si)₂Te, (Me₃Si)₂Te, (ⁱPr₃Si)₂Te, (^{t}BuMe₂Si)₂Te, (Me₂Si)₂Te₂, (Me₂SiC₂H₄SiMe₂)Te, (Me₂SiSiMe₂)₂Te₂, Me₈Si₄Te₂, Te(GeMe₃)₂, (Me₃Si)₃Sb, (Et₃Si)₃Sb, (Et₃Si)₃As, (Et₃Ge)₂Te, (Me₃Ge)₂Te, (ⁱPr₃Ge)₂Te, (^{t}BuMe₂Ge)₂Te, (Me₂Ge)₂Te₂, (Me₂GeC₂H₄GeMe₂)Te, (Me₂2)₂Te₂, Me₈Ge₄Te₂, Te(GeMe₃)₂, (Me₃Ge)₃Sb, (Et₃Ge)₃Sb and (Et₃Ge)₃As.

In some embodiments, the first precursor comprises (R₃Si)₂Te where R is a C1-C4 alkyl.

In some embodiments, the first precursor comprises a compound selected from the group of general formulas consisting of (R₂Si)₂E₂, (R₂SiC₂R₄SiR₂) E and (R₂SiSiR₂)₂E, wherein E=Te or Se and each R is independently selected from C1-C4 alkyls.

In some embodiments, the first precursor comprises (Et₃Si)₂Te.

In some embodiments, the second precursor comprises a compound selected from the group consisting of BBr₃, BCl₃, Si₂Cl₆, SiCl₂H₂, Si₂Cl₅H, SiCl₄, SiCl₂Me₂, SiI₄, GeCl₄, Ge(thd)Cl, GeCl₂·dioxane, HGeCl₃, SbCl₃, SbCl₅, AsCl₅, AsCl5, Se₂Cl₂, SeCl₂, SeCl₄ and TeCl₂.

In one aspect, a method for deposing metalloid-containing material on a substrate by a cyclic deposition process is disclosed. The method comprises a super cycle which comprises providing a substrate into a reaction chamber and two sub-cycles. The first sub-cycle comprises providing a first precursor into the reaction chamber in vapor phase; and providing a second precursor into the reaction chamber in vapor phase. The second sub-cycle comprises providing a first precursor into the reaction chamber in vapor phase; and providing a third precursor into the reaction chamber in vapor phase. In the method the first precursor comprises metalloid alkyl silyl, the second precursor comprises metalloid halide, the third precursor comprises metalloid halide, and the second precursor and the third precursor are mutually different.

In some embodiments, the first precursor is selected from the group consisting of (Et₃Si)₂Te, (Me₃Si)₂Te, (ⁱPr₃Si)₂Te, (^{t}BuMe₂Si)₂Te, (Me₂Si)₂Te₂, (Me₂SiC₂H₄SiMe₂)Te, (Me₂SiSiMe₂)₂Te₂, Me₈Si₄Te₂, Te(GeMe₃)₂, (Me₃Si)₃Sb, (Et₃Si)₃Sb, (Et₃Si)₃As, (Et₃Ge)₂Te, (Me₃Ge)₂Te, (ⁱPr₃Ge)₂Te, (^{t}BuMe₂Ge)₂Te, (Me₂Ge)₂Te₂, (Me₂GeC₂H₄GeMe₂)Te, (Me₂GeGeMe2)₂Te₂, Me₈Ge₄Te₂, Te(GeMe₃)₂, (Me₃Ge)₃Sb, (Et₃Ge)₃Sb and (Et₃Ge)₃As.

In some embodiments, the second precursor and third precursor are independently selected from the group consisting of BBr₃, BCl₃, Si₂Cl₆, SiCl₂H₂, Si₂Cl₅H, SiCl₄, SiCl₂Me₂, Sil₄, GeCl₄, Ge(thd)Cl, GeCl₂·dioxane, HGeCl3, SbCl₃, SbCl₅, AsCl₅, AsCl₅, Se₂Cl₂, SeCl₂, SeCl₄ and TeCl₂.

In one aspect, a metalloid-containing layer produced by a cyclic deposition process is disclosed. The deposition process comprises providing a substrate in a reaction chamber; providing a first precursor into the reaction chamber is vapor phase; and providing a second precursor into the reaction chamber in vapor phase. In the process at least one of the first precursor and the second precursor comprise a metalloid compound.

In some embodiments, the layer comprises elemental metalloid.

In one aspect, a semiconductor structure comprising a metalloid-containing layer deposited by a cyclic deposition process is disclosed. The process comprises providing a substrate in a reaction chamber; providing a first precursor into the reaction chamber is vapor phase; and providing a second precursor into the reaction chamber in vapor phase. In the process, at least one of the first precursor and the second precursor comprise a metalloid compound.

In one aspect, a semiconductor device comprising a metalloid-containing layer deposited by a cyclic deposition process is disclosed. The process comprises providing a substrate in a reaction chamber; providing a first precursor into the reaction chamber in vapor phase; and providing a second precursor into the reaction chamber in vapor phase. In the process, at least one of the first precursor and the second precursor comprise a metalloid compound.

In one aspect, a deposition assembly for depositing metalloid-containing material on a substrate is provided. The assembly comprises one or more reaction chambers constructed and arranged to hold the substrate; a precursor injector system constructed and arranged to provide a first precursor and a second precursor into the reaction chamber in a vapor phase. At least one of the first precursor and the second precursor comprise a metalloid compound. The deposition assembly further comprises a precursor vessel constructed and arranged to contain a first precursor. The deposition assembly further comprises a precursor vessel constructed and arranged to contain a second precursor. The assembly is constructed and arranged to provide the first precursor and the second precursor via the precursor injector system to the reaction chamber to deposit metalloid-containing material on the substrate.

### BRIEF DESCRIPTION OF THE DRAWING FIGURES

The accompanying drawings, which are included to provide a further understanding of the disclosure and constitute a part of this specification, illustrate exemplary embodiments, and together with the description help to explain the principles of the disclosure. In the drawings

FIGS. 1A and 1B illustrate a block diagram of embodiments of a method according to the current disclosure.

FIGS. 2A and 2B illustrate a block diagram of embodiments of a method according to the current disclosure.

FIG. 3 is a schematic presentation of a deposition assembly according to the current disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

In this disclosure, any two numbers of a variable can constitute a workable range of the variable, and any ranges indicated may include or exclude the endpoints.

Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments.

“At least one”, “one or more”, and “and/or” are open-ended expressions that are both conjunctive and disjunctive in operation. For example, each of the expressions “at least one of A, B, and C”, “at least one of A, B, or C”, “one or more of A, B, and C”, “one or more of A, B, or C” and “A, B, and/or C” means A alone, B alone, C alone, A and B together, A and C together, B and C together, or A, B and C together. When each one of A, B, and C in the above expressions refers to an element, such as X, Y, and Z, or class of elements, such as X₁-Xₙ, Y₁-Yₘ, and Z₁-Zₒ, the phrase is intended to refer to a single element selected from X, Y, and Z, a combination of elements selected from the same class (e.g., X₁ and X₂) as well as a combination of elements selected from two or more classes (e.g., Y₁ and Zₒ).

In an aspect, a method of depositing metalloid material on a substrate by a cyclic deposition process is disclosed. In a cyclic deposition process, the phases of providing the first precursor and providing the second precursor are repeated until a desired material thickness is achieved.

In the methods according to the current disclosure, the material deposited on a substrate comprises metalloid material. In some embodiments, the metalloid material comprises tellurium. In some embodiments, the metalloid material comprises germanium. In some embodiments, the metalloid material comprises tin. In some embodiments, the metalloid material comprises antimony. In some embodiments, the metalloid material comprises arsenic. In some embodiments, the metalloid material comprises selenium. In some embodiments, the metalloid material comprises elemental metalloid. In some embodiments, the metalloid material comprises metalloid alloy.

As used herein, the term “layer” and/or “film” can refer to any continuous or noncontinuous structure and material, such as material deposited by the methods disclosed herein. For example, layer and/or film can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous. A seed layer may be a noncontinuous layer serving to increase the rate of nucleation of another material. However, the seed layer may also be substantially or completely continuous. A layer of desired thickness may be deposited by repeating providing a first precursor and a second precursor in the reaction chamber sufficiently many times. A layer produced according to the methods disclosed herein may form a part of a semiconductor structure and/or a semiconductor device.

In a further aspect, a semiconductor structure comprising a metalloid layer deposited by a cyclic deposition process is disclosed. The cyclic deposition process is performed as described herein, and the process is integrated with additional processing steps to produce the semiconductor structure. The semiconductor structure may be a part of a semiconductor device. Such devices are used in the manufacture of integrated circuits.

In some embodiments, the metalloid material is deposited as a layer on a substrate. In some embodiments, the metalloid layer comprises elemental metalloid. The thickness of a metalloid material layer may be regulated by adjusting the cycle number of the cyclic deposition process. In some embodiments, the cyclic deposition process comprises providing the first precursor and the second precursor alternately and sequentially into the reaction chamber. In some embodiments, the reaction chamber is purged between providing precursors into the reaction chamber. Examples of such cyclic deposition processes are atomic layer deposition and cyclic chemical vapor deposition.

As used herein, the term “substrate” may refer to any underlying material or materials that may be used to form, or upon which, a device, a circuit, material or a material layer may be formed. A substrate can include a bulk material, such as silicon (such as single-crystal silicon), other Group IV materials, such as germanium, or other semiconductor materials, such as a Group II-VI or Group III-V semiconductor materials. A substrate can include one or more layers overlying the bulk material. The substrate can include various topologies, such as gaps, including recesses, lines, trenches or spaces between elevated portions, such as fins, and the like formed within or on at least a portion of a layer of the substrate. Substrate may include nitrides, for example, TiN, oxides, insulating materials, dielectric materials, conductive materials, metals, such as tungsten, ruthenium, molybdenum, cobalt, aluminum or copper, or metallic materials, crystalline materials, epitaxial, heteroepitaxial, and/or single crystal materials. In some embodiments of the current disclosure, the substrate comprises silicon. The substrate may comprise other materials, as described above, in addition to silicon. The other materials may form layers.

In the current disclosure, the deposition process comprises a cyclic deposition process, such as an atomic layer deposition (ALD) process or a cyclic chemical vapor deposition (CVD) process. The term “cyclic deposition process” can refer to the sequential introduction of precursor(s) and/or reactant(s) into a reaction chamber to deposit material, such as metalloid, on a substrate. Cyclic deposition includes processing techniques such as atomic layer deposition (ALD), cyclic chemical vapor deposition (cyclic CVD), and hybrid cyclic deposition processes that include an ALD component and a cyclic CVD component. The process may comprise a purge step between providing precursors or between providing a precursor and a reactant in the reaction chamber.

The process may comprise one or more cyclic phases. For example, pulsing of a first precursor and a second precursor may be repeated. Repeating the cyclic deposition steps may be used to control the thickness of the deposited material. In some embodiments, the process comprises one or more acyclic phases. In some embodiments, the deposition process comprises the continuous flow of at least one precursor. In some embodiments, a reactant may be continuously provided in the reaction chamber. In such an embodiment, the process comprises a continuous flow of a precursor or a reactant. In some embodiments, one or more of the precursors and/or reactants are provided in the reaction chamber continuously. A cyclic deposition process may usually be initiated with any of at least two precursors and/or reactants used in the process. Thus, in the current methods, the first deposition cycle may be started by providing either a first precursor or a second precursor in the reaction chamber.

The term “atomic layer deposition” (ALD) can refer to a vapor deposition process in which deposition cycles, such as a plurality of consecutive deposition cycles, are conducted in a reaction chamber. The term “atomic layer deposition”, as used herein, is also meant to include processes designated by related terms, such as chemical vapor atomic layer deposition, when performed with alternating pulses of precursor(s)/reactant(s), and optional purge gas(es). Generally, for ALD processes, during each cycle, a precursor is introduced to a reaction chamber and is chemisorbed to a deposition surface (e.g., a substrate surface that may include a previously deposited material from a previous ALD cycle or other material), forming about a monolayer or sub-monolayer of material that does not readily react with additional precursor (i.e., a self-limiting reaction). Thereafter, in some cases, another precursor or a reactant may subsequently be introduced into the process chamber for use in converting the chemisorbed precursor to the desired material on the deposition surface. The second precursor or a reactant can be capable of further reaction with the precursor.

Purging steps may be utilized during one or more cycles, e.g., during each step of each cycle, to remove any excess precursor from the process chamber and/or remove any excess second precursors, reactant and/or reaction byproducts from the reaction chamber. Thus, in some embodiments, the cyclic deposition process comprises purging the reaction chamber after providing a precursor into the reaction chamber. In some embodiments, the cyclic deposition process comprises purging the reaction chamber after providing a first precursor into the reaction chamber. In some embodiments, the cyclic deposition process comprises purging the reaction chamber after providing a second precursor into the reaction chamber. In some embodiments, the cyclic deposition process comprises purging the reaction chamber after providing each precursor into the reaction chamber.

CVD type processes typically involve gas phase reactions between two or more precursors and/or reactants. The precursor(s) and reactant(s) can be provided simultaneously to the reaction space or substrate, or in partially or completely separated pulses. The substrate and/or reaction space can be heated to promote the reaction between the gaseous precursor and/or reactants. In some embodiments, the precursor(s) and reactant(s) are provided until a layer having a desired thickness is deposited. In some embodiments, cyclic CVD processes can be used with multiple cycles to deposit a thin film having a desired thickness. In cyclic CVD processes, the precursors and/or reactants may be provided to the reaction chamber in pulses that do not overlap, or that partially or completely overlap.

As used herein, the term “purge” may refer to a procedure in which vapor phase precursors and/or vapor phase byproducts are removed from the substrate surface, for example, by evacuating the reaction chamber with a vacuum pump and/or by replacing the gas inside a reaction chamber with an inert or substantially inert gas, such as argon or nitrogen. Purging may be effected between two pulses of gases which react with each other. However, purging may be effected between two pulses of gases that do not react with each other. For example, a purge, or purging may be provided between pulses of two precursors or between a precursor and a reactant. Purging may avoid or at least reduce gas-phase interactions between the two gases reacting with each other. It shall be understood that a purge can be effected either in time or in space, or both. For example, in the case of temporal purges, a purge step can be used e.g., in the temporal sequence of providing a first precursor to a reactor chamber, providing a purge gas to the reactor chamber, and providing a second precursor to the reactor chamber, wherein the substrate on which a layer is deposited does not move. For example, in the case of spatial purges, a purge step can take the following form: moving a substrate from a first location to which a first precursor is continually supplied, through a purge gas curtain, to a second location to which a second precursor is continually supplied.

Purging times may be, for example, from about 0.01 seconds to about 20 seconds, from about 0.05 s to about 20 s, or from about 1 s to about 20 s, or from about 0.5 s to about 10 s, or between about 1 s and about 7 seconds, such as 1 s or 2 s. However, other purge times can be utilized if necessary, such as where highly conformal step coverage over extremely high aspect ratio structures or other structures with complex surface morphology is needed, or in specific reactor types, such as a batch reactor, may be used.

In some embodiments, the cyclic deposition process according to the current disclosure comprises a thermal deposition process. In a thermal deposition process, the chemical reactions may be promoted by increased temperature relevant to ambient temperature. Generally, a temperature increase may provide the energy needed for the formation of metalloid material in the absence of other external energy sources, such as plasma, radicals, or other forms of radiation. In some embodiments, the method according to the current disclosure is a plasma-enhanced deposition method, for example, PEALD or PECVD.

The methods according to the current disclosure comprise providing a substrate in a reaction chamber, providing a first precursor into the reaction chamber in vapor phase, and providing a second precursor into the reaction chamber in vapor phase to form elemental metalloid material on the substrate.

The method of depositing metalloid material according to the current disclosure comprises providing a substrate in a reaction chamber. In other words, a substrate is brought into space where the deposition conditions can be controlled. The reaction chamber may be part of a cluster tool in which different processes are performed to form an integrated circuit. In some embodiments, the reaction chamber may be a flow-type reactor, such as a cross-flow reactor. In some embodiments, the reaction chamber may be a showerhead reactor. In some embodiments, the reaction chamber may be a space-divided reactor. In some embodiments, the reaction chamber may be single wafer ALD reactor. In some embodiments, the reaction chamber may be a high-volume manufacturing single wafer ALD reactor. In some embodiments, the reaction chamber may be a batch reactor for manufacturing multiple substrates simultaneously. A reaction chamber according to the current disclosure may further be a deposition station in a multi-station chamber.

Further, in the method according to the current disclosure, a first precursor is provided into the reaction chamber in a vapor phase, and a second precursor is provided into the reaction chamber in a vapor phase to form metalloid material on the substrate.

In the method according to the current disclosure, the first precursor may be in vapor phase when it is in a reaction chamber. The first precursor may be partially gaseous or liquid, or even solid at some points in time prior to being provided in the reaction chamber. In other words, a first precursor may be solid, liquid or gaseous, for example, in a precursor vessel or other receptacle before delivery in a reaction chamber. Various means of bringing the precursor in to gas phase can be applied when delivery into the reaction chamber is performed. Such means may include, for example, heaters, vaporizers, gas flow or applying lowered pressure, or any combination thereof. Thus, the method according to the current disclosure may comprise heating the first precursor prior to providing it to the reaction chamber. In the method according to the current disclosure, the second precursor may be in vapor phase when it is in a reaction chamber. The second precursor may be partially gaseous or liquid, or even solid at some points in time prior to being provided in the reaction chamber. In other words, a second precursor may be solid, liquid or gaseous, for example, in a precursor vessel or other receptacle before delivery in a reaction chamber. Various structures or methods for bringing the precursor in to gas phase can be applied when delivery into the reaction chamber is performed. Such structures or methods for may include, for example, heaters, vaporizers, gas flow or applying lowered pressure, or any combination thereof. Thus, the method according to the current disclosure may comprise heating the second precursor prior to providing it to the reaction chamber.

In some embodiments, the deposition of metalloid material according to the current disclosure if performed at a temperature below about 200° C., or below about 170° C., or below about 120° C. In some embodiments, the deposition is performed at a temperature from about 70° C. to about 130° C., for example from about 85°° C. to about 115° C., such as at a temperature of about 90° C., about 100° C. or at about 110° C.

In some embodiments, a first precursor is heated to at least 20° C., or to at least 25° C., or to at least 30° C. or to at least 35° C. or to at least 40° C. before providing the first precursor to the reaction chamber. The heating may take place in a precursor vessel. In some embodiments, the first precursor is heated to at most 50° C., or to at most 45° C. before providing it to the reaction chamber. The injector system of a vapor deposition assembly may be heated to improve the vapor-phase delivery of the first precursor to the reaction chamber.

In some embodiments, a second precursor is heated to at least 50° C., or to at least 60° C., or to at least 65° C. or to at least 70° C. or to at least 75° C. before providing it to the reaction chamber. The heating may take place in a precursor vessel. In some embodiments, the second precursor is heated to at most 90° C., or to at most 85° C., or to at most 80°° C. before providing it to the reaction chamber. The injector system of a vapor deposition assembly may be heated to improve the vapor-phase delivery of the second precursor to the reaction chamber.

In this disclosure, “gas” can include material that is a gas at normal temperature and pressure (NTP), a vaporized solid and/or a vaporized liquid, and can be constituted by a single gas or a mixture of gases, depending on the context. A first precursor may be provided to the reaction chamber in gas phase. A second precursor may be provided to the reaction chamber in gas phase. The term “inert gas” can refer to a gas that does not take part in a chemical reaction and/or does not become a part of a layer to an appreciable extent. Exemplary inert gases include He, Ar, or any combination thereof. In some cases, molecular nitrogen and/or hydrogen can be an inert gas. A gas other than a process gas, i.e., a gas introduced without passing through a precursor injector system, other gas distribution device, or the like, can be used for, e.g., sealing the reaction space, and can include a seal gas.

In some embodiments, the metalloid material comprises elemental metalloid. In this disclosure, “metalloid” includes the group of material between the metals and nonmetals in the periodic table. The metalloids include boron, silicon, germanium, arsenic, antimony, selenium and tellurium. Thus, the deposited metalloid may at least partly have an oxidation state of 0. In some embodiments, substantially all or all of the metalloid is deposited as elemental metalloid. In some embodiments, the deposited metalloid comprises, consists essentially of, or consists of elemental tellurium. In some embodiments, the deposited metalloid comprises, consists essentially of, or consists of elemental germanium. In some embodiments, the deposited metalloid comprises, consists essentially of, or consists of elemental arsenic. In some embodiments, the deposited metalloid comprises, consists essentially of, or consists of elemental antimony. In some embodiments, a layer consisting essentially of, or consisting of, elemental metalloid is deposited. In some embodiments, the metalloid according to the current disclosure is deposited as a layer, and the layer comprises substantial amounts of other elements in addition to the metalloid. In such embodiments, the metalloid may be present as elemental metalloid. In some embodiments, the metalloid deposited according to the current disclosure is present as an alloy with another metalloid.

The growth rate of metalloid material may be, for example from about 0.05 to about 1.5 Å/cycle. The growth rate and the layer properties may depend on the temperature at which the deposition process is performed. In some embodiments, the growth rate may be about 0.1 Å/cycle, or about 0.2 Å/cycle, or about 0.5 Å/cycle, or about 1 Å/cycle, or about 1.2 Å/cycle. The growth rate may vary during a deposition process.

The deposition cycle, comprising providing first precursor into the reaction chamber (i.e., pulsing the first precursor) and providing the second precursor into the reaction chamber (i.e., pulsing the second precursor), as well as optional purging phases, may be repeated, for example about 100 times, about 125 times, about 200 times, about 250 times, about 350 times, about 500 times, about 750 times, about 1,000 times or about 1,500 times. In some embodiments, the deposition cycle may be repeated for at least about 100 times, about 250 times, at least about 350 times, at least about 500 times, at least about 750 times, at least about 1,000 times or at least about 1,500 times.

The terms “precursor” and “reactant” can refer to molecules (compounds or molecules comprising a single element) that participate in a chemical reaction that produces another compound. A precursor typically contains portions that are at least partly incorporated into the compound or element resulting from the chemical reaction in question. Such a resulting compound or element may be deposited on a substrate. A reactant may be an element or a compound that is not incorporated into the resulting compound or element to a significant extent. However, a reactant may also contribute to the resulting compound or element in certain embodiments.

In the methods according to the current disclosure, the first precursor comprises an alkyl silyl group and/or a silyl group.

In some embodiments, the first precursor comprises metalloid alkyl silyl or metalloid silyl. In some embodiments, the alkyl is a C1-C4 alkyl.

In some embodiments, the metalloid in the first precursor is selected form the group consisting of tellurium, germanium, boron, silicon, arsenic, selenium and antimony. In some embodiments, the metalloid in the first precursor comprises tellurium or germanium. In some embodiments, the first precursor comprises tellurium.

In some embodiments, the first precursor comprises a compound selected from the group of general formulas consisting of (R₂Si)₂E₂, (R₂SiC₂R₄SiR₂)E and (R₂SiSiR₂)₂E₂, wherein E=is a metalloid selected from the group consisting of tellurium, germanium, boron, silicon, arsenic, antimony and selenium and each R is independently selected from C1-C4 alkyls. In some embodiments, the first precursor comprises a compound selected from the group of general formulas consisting of (R₂Si)₂E₂, (R₂SiC₂R₄SiR₂)E and (R₂SiSiR₂)₂E, wherein E=Te or Se and each R is independently selected from a C1-C4 alkyl.

In some embodiments, the first precursor is selected from the group consisting of (Et₃Si)₂Te, (Me₃Si)₂Te, (ⁱPr₃Si)₂Te, (^{t}BuMe₂Si)₂Te, (Me₂Si)₂Te₂, (Me₂SiC₂H₄SiMe₂)Te, (Me₂SiSiMe₂)₂Te₂, Me₈Si₄Te₂, Te(GeMe₃)₂, (Me₃Si)₃Sb, (Et₃Si)₃Sb, (Et₃Si)₃As, (Et₃Ge)₂Te, (Me₃Ge)₂Te, (ⁱPr₃Ge)₂Te, (^{t}BuMe₂Ge)₂Te, (Me₂Ge)₂Te₂, (Me₂GeC₂H₄GeMe₂)Te, (Me₂GeGeMe2)₂Te₂, Me₈Ge₄Te₂, Te(GeMe₃)₂, (Me₃Ge)₃Sb, (Et₃Ge)₃Sb and (Et₃Ge)₃As.

In some embodiments, the first precursor comprises (R₃Si)₂Te where R is a C1-C4 alkyl.

In some embodiments, the alkyl is ethyl.

In some embodiments, the first precursor comprises (Et₃Si)₂Te.

The metalloid material is formed by providing a second precursor into the reaction chamber in a vapor phase. The conversion of a first precursor to the desired metalloid material may take place at the substrate surface. In some embodiments, the conversion may take place at least partially in the gas phase. In some embodiments, the reactions between the first precursor and the second precursor take place substantially only on the surface of the substrate.

In some embodiments, the second precursor comprises a halide. In some embodiments, the second precursor comprises a metalloid halide. In some embodiments, the halide is selected from the group consisting of chlorine, bromine, fluorine and iodine.

In some embodiments, the metalloid in the second precursor is selected form the group consisting of tellurium, germanium, boron, silicon, arsenic, selenium and antimony. In some embodiments, the metalloid comprises tellurium or germanium. In some embodiments, the metalloid in at least one of the first precursor or the second precursor comprises tellurium. In some embodiments, the metalloid in the first precursor and the second precursor is tellurium. In some embodiments, the metalloid in the first precursor is tellurium and the metalloid in the second precursor is germanium.

In some embodiments, the second precursor is selected from the group consisting of BBr₃, BCl₃, Si₂Cl₆, SiCl₂H₂, Si₂Cl₅H, SiCl₄, SiCl₂Me₂, SiI₄, GeCl₄, Ge(thd)Cl, GeCl₂·dioxane, HGeCl₃, SbCl₃, SbCl₅, AsCls₅, AsCl₅, Se₂Cl₂, SeCl₂, SeCl₄ and TeCl₂. In some embodiments, the second precursor comprises TeCl₂ or GeCl₂·dioxane.

In one aspect, a method for deposing metalloid-containing material on a substrate by a cyclic deposition process is disclosed. The method comprises a super cycle which comprises providing a substrate into a reaction chamber and two sub-cycles. The first sub-cycle comprises providing a first precursor into the reaction chamber is vapor phase; and providing a second precursor into the reaction chamber in vapor phase. The second sub-cycle comprises providing a first precursor into the reaction chamber in vapor phase; and providing a third precursor into the reaction chamber in vapor phase.

In some embodiments, the first precursor comprises metalloid alkyl silyl, the second precursor comprises metalloid halide, the third precursor comprises metalloid halide, and the second precursor and the third precursor are mutually different.

In some embodiments, the first precursor is selected from the group consisting of (Et₃Si)₂Te, (Me₃Si)₂Te, (ⁱPr₃Si)₂Te, (^{t}BuMe₂Si)₂Te, (Me₂Si)₂Te₂, (Me₂SiC₂H₄SiMe₂)Te, (Me₂SiSiMe₂)₂Te₂, Me₈Si₄Te₂, Te(GeMe₃)₂, (Me₃Si)₃Sb, (Et₃Si)₃Sb, (Et₃Si)₃As, (Et₃Ge)₂Te, (Me₃Ge)₂Te, (ⁱPr₃Ge)₂Te, (^{t}BuMe₂Ge)₂Te, (Me₂Ge)₂Te₂, (Me₂GeC₂H₄GeMe₂)Te, (Me₂GeGeMe2)₂Te₂, Me₈Ge₄Te₂, Te(GeMe₃)₂, (Me₃Ge)₃Sb, (Et₃Ge)₃Sb and (Et₃Ge)₃As. In some embodiments the first precursor comprises (Et₃Si)₂Te.

In some embodiments, the second precursor and third precursor are selected from the group consisting of BBr₃, BCl₃, Si2Cl₆, SiCl₂H₂, Si₂Cl₅H, SiCl₄, SiCl₂Me₂, Sil₄, GeCl₄, Ge(thd)Cl, GeCl₂·dioxane, HGeCl₃, SbCl₃, SbCl₅, AsCl₅, AsCl₅, Se₂Cl₂, SeCl₂, SeCl₄ and TeCl₂. In some embodiments, the second precursor comprises TeCl₂ and the third precursor comprises GeCl₂·dioxane.

In one aspect, a metalloid-containing layer produced by a cyclic deposition process is disclosed. The deposition process comprises providing a substrate in a reaction chamber; providing a first precursor into the reaction chamber is vapor phase; and providing a second precursor into the reaction chamber in vapor phase. In the process, at least one of the first precursor or the second precursor comprises a metalloid compound. In some embodiments, the metalloid-containing layer comprises elemental metalloid.

In one aspect, a semiconductor structure comprising a metalloid-containing layer deposited by a cyclic deposition process is disclosed. The process comprises providing a substrate in a reaction chamber; providing a first precursor into the reaction chamber is vapor phase; and providing a second precursor into the reaction chamber in vapor phase. In the process, at least one of the first precursor and the second precursor comprise a metalloid compound.

In one aspect, a semiconductor device comprising a metalloid-containing layer deposited by a cyclic deposition process is disclosed. The process comprises providing a substrate in a reaction chamber; providing a first precursor into the reaction chamber is vapor phase; and providing a second precursor into the reaction chamber in vapor phase. In the process, at least one of the first precursor and the second precursor comprise a metalloid compound.

In one aspect, a vapor deposition assembly for depositing metalloid-containing material on a substrate is provided. The assembly comprises one or more reaction chambers constructed and arranged to hold the substrate; a precursor injector system constructed and arranged to provide a first precursor; and a second precursor into the reaction chamber in a vapor phase. At least one of the first precursor or the second precursor comprise a metalloid compound. The deposition assembly further comprises a precursor vessel constructed and arranged to contain a first precursor.

The deposition assembly further comprising a precursor vessel constructed and arranged to contain a second precursor. The assembly is constructed and arranged to provide the first precursor and the second precursor via the precursor injector system to the reaction chamber to deposit metalloid-containing material on the substrate.

In some embodiments, the vapor deposition assembly may additionally include control processors and software configured to operate the reaction chamber to perform an ALD process. In some embodiments, the vapor deposition assembly may additionally include control processors and software configured to operate the reaction chamber to perform a CVD process.

The subject matter of the present disclosure includes all novel and nonobvious combinations and subcombinations of the various processes, systems, and configurations, and other features, functions, acts, and/or properties disclosed herein, as well as any and all equivalents thereof.

The illustrations presented herein are not meant to be actual views of any particular material, structure, or device, but are merely idealized representations that are used to describe embodiments of the disclosure.

The particular implementations shown and described are illustrative of the invention and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

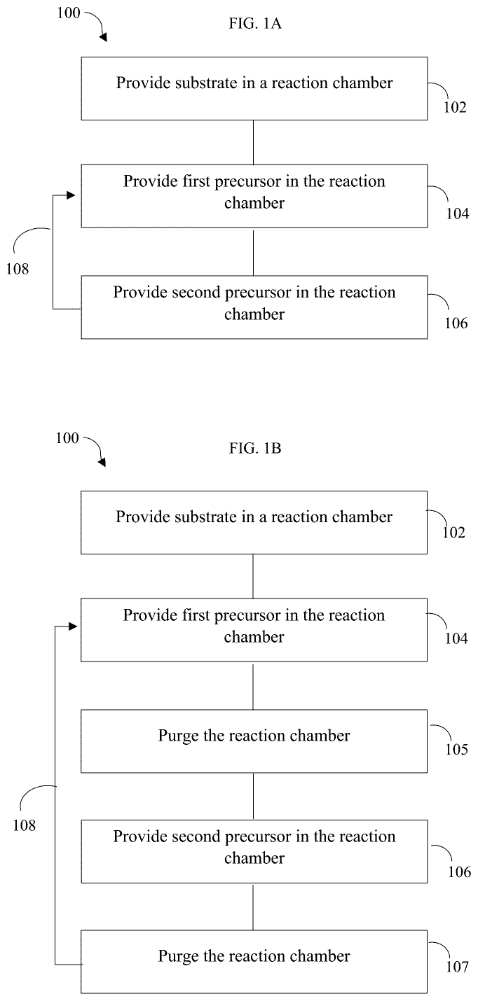

FIGS. 1A and 1B illustrate a block diagram of an exemplary embodiment of a method 100 of depositing metalloid material on a substrate. In the first phase 102, a substrate is provided into a reaction chamber. A substrate according to the current disclosure may comprise, for example, an oxide, such as silicon oxide (for example, thermal silicon oxide or native silicon oxide). A substrate may comprise a nitride, such as silicon nitride or titanium nitride, a metal, such as copper, cobalt, tungsten, or a chalcogenide material, such as molybdenum sulfide. The metalloid material according to the current disclosure may be deposited on said surfaces.

The reaction chamber can form part of an atomic layer deposition (ALD) assembly. The reaction chamber can form part of a chemical vapor deposition (CVD) assembly. The assembly may be a single wafer reactor. Alternatively, the reactor may be a batch reactor. The assembly may comprise one or more multi-station deposition chambers. Various phases of method 100 can be performed within a single reaction chamber or they can be performed in multiple reaction chambers, such as reaction chambers of a cluster tool.

In some embodiments, the method 100 is performed in a single reaction chamber of a cluster tool, but other, preceding or subsequent, manufacturing steps of the structure or device are performed in additional reaction chambers of the same cluster tool. Optionally, an assembly including the reaction chamber can be provided with a heater to activate the reactions by elevating the temperature of one or more of the substrate and/or the reactants and/or precursors. The metalloid material according to the current disclosure may be deposited in a cross-flow reaction chamber. The metalloid material according to the current disclosure may be deposited in a showerhead reaction chamber.

A first precursor is provided in the reaction chamber containing the substrate 104. Without limiting the current disclosure to any specific theory, the first precursor may chemisorb on the substrate during providing first precursor into the reaction chamber. The duration of providing a first precursor into the reaction chamber (first precursor pulse time) may be, for example, 0.5 seconds, 1 second, 1.5 seconds, 2 seconds, 2,5 seconds, 3 seconds, 4 seconds or 5 seconds.

In the second deposition phase 106 of method 100, a second precursor is provided in the reaction chamber. Without limiting the current disclosure to any specific theory, the second precursor may react with the chemisorbed first precursor. The duration of providing the second precursor into the reaction chamber (second precursor pulse time) may be, for example, 0.5 seconds, 1 second, 1.5 seconds, 2 seconds, 2,5 seconds, 3 seconds, 4 seconds or 5 seconds.

Phases of providing a first precursor 104 and providing a second precursor 106 may be performed in any order. The phases of providing a first precursor 104 and providing a second precursor 106 may constitute a deposition cycle, resulting in the deposition of metalloid material. In some embodiments, the two phases of metalloid material deposition, namely providing the first precursor and the second precursor in the reaction chamber (104 and 106), may be repeated (loop 108). Such embodiments contain several deposition cycles. The thickness of the deposited metalloid material may be regulated by adjusting the number of deposition cycles. The deposition cycle (loop 108) may be repeated until a desired metalloid material thickness is achieved. For example, about 50, 100, 200, 300, 400, 500, 700, 800,1,000, 1,200, 1,500, 2,000, 2,400 or 3,000 deposition cycles may be performed. The cyclical deposition may result in the formation of a metalloid layer. The layer may be substantially continuous or continuous.

In some embodiments, the cyclic deposition process comprises providing the first precursor and the second precursor alternately and sequentially in the reaction chamber. In some embodiments, the reaction chamber is purged between precursors, 105, 107, as depicted in FIG. 1B. In such embodiments, a deposition cycle may be considered to contain phases 104, 105, 106 and 107. As above, a deposition cycle may be repeated 108 a number of times to achieve desired metalloid material thickness.

The first precursor and second precursor may be provided in the reaction chamber in separate steps (104 and 106). FIG. 1B illustrates an embodiment according to the current disclosure, where steps 104 and 106 are separate by purge steps 105 and 107. In such embodiments, a deposition cycle comprises one or more purge steps 103, 105. During purge steps, precursor and/or reactant can be temporally separated from each other by inert gases, such as argon (Ar), nitrogen (N₂) or helium (He) and/or a vacuum pressure. The separation of first precursor and second precursor may alternatively be spatial.

Purging the reaction chamber 103, 105 may prevent or mitigate gas-phase reactions between the first precursor and the second precursor, and enable possible self-saturating surface reactions. Surplus chemicals and reaction byproducts, if any, may be removed from the substrate surface, such as by purging the reaction chamber or by moving the substrate, before the substrate is contacted with the next reactive chemical. In some embodiments, however, the substrate may be moved to separately contact a first precursor and a second precursor. Because, in some embodiments, the reactions may self-saturate, strict temperature control of the substrates and precise dosage control of the precursors may not be required. However, the substrate temperature is preferably such that an incident gas species does not condense into monolayers or multimonolayers nor thermally decompose on the surface.

When performing the method 100, metalloid material is deposited onto the substrate. The deposition process may be a cyclical deposition process, and may include cyclical CVD, ALD, or a hybrid cyclical CVD/ALD process. For example, in some embodiments, the growth rate of a particular ALD process may be low compared with a CVD process. One approach to increase the growth rate may be that of operating at a higher deposition temperature than that typically employed in an ALD process, resulting in some portion of a chemical vapor deposition process, but still taking advantage of the sequential introduction of a first precursor and a second precursor. Such a process may be referred to as cyclical CVD. In some embodiments, a cyclical CVD process may comprise the introduction of two or more precursors into the reaction chamber, wherein there may be a time period of overlap between the two or more precursors in the reaction chamber resulting in both an ALD component of the deposition and a CVD component of the deposition. This is referred to as a hybrid process. In some embodiments, a cyclical deposition process may comprise the continuous flow of one reactant or precursor and the periodic pulsing of the other chemical component into the reaction chamber. The temperature and/or pressure within a reaction chamber during step 104 can be the same or similar to any of the pressures and temperatures noted above in connection with step 102.

In some embodiments, the first precursor is brought into contact with a substrate surface 104, excess first precursor is partially or substantially completely removed by an inert gas or vacuum 105, and second precursor is brought into contact with the substrate surface comprising first precursor. First precursor may be brought in to contact with the substrate surface in one or more pulses 104. In other words, pulsing of the first precursor 104 may be repeated. The first precursor on the substrate surface may react with the second precursor to form metalloid material on the substrate surface. Also pulsing of the second precursor 106 may be repeated. In some embodiments, second precursor may be provided in the reaction chamber first 106. Thereafter, the reaction chamber may be purged 105 and first precursor provided in the reaction chamber in one or more pulses 104.

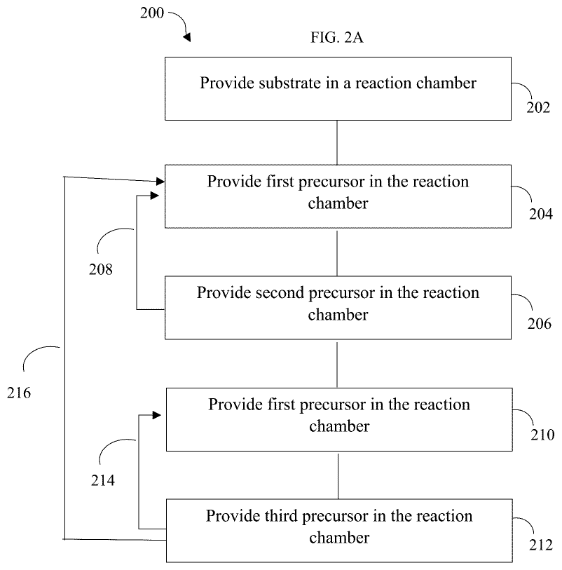

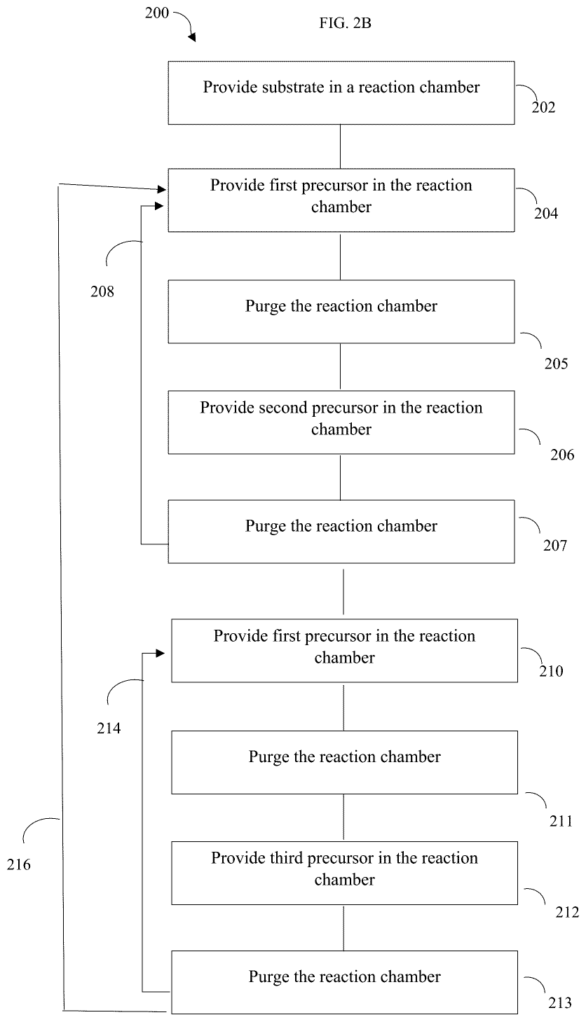

FIGS. 2A and 2B illustrate a block diagram of another embodiment of a method 200 of depositing metalloid material on a substrate. In the first phase 202, a substrate is provided into a reaction chamber. A substrate according to the current disclosure may comprise, for example, an oxide, such as silicon oxide (for example, thermal silicon oxide or native silicon oxide). A substrate may comprise a nitride, such as silicon nitride or titanium nitride, a metal, such as copper, cobalt or tungsten, chalcogenide material, such as molybdenum sulfide. A metalloid material according to the current disclosure may be deposited on said surfaces.

The reaction chamber can form part of an atomic layer deposition (ALD) assembly. The reaction chamber can form part of a chemical vapor deposition (CVD) assembly. The assembly may be a single wafer reactor. Alternatively, the reactor may be a batch reactor. The assembly may comprise one or more multi-station deposition chambers. Various phases of methods disclosed herein can be performed within a single reaction chamber or they can be performed in multiple reaction chambers, such as reaction chambers of a cluster tool. In some embodiments, the methods as disclosed herein are performed in a single reaction chamber of a cluster tool, but other, preceding or subsequent, manufacturing steps of the structure or device are performed in additional reaction chambers of the same cluster tool. Optionally, an assembly including the reaction chamber can be provided with a heater to activate the reactions by elevating the temperature of one or more of the substrate and/or the reactants and/or precursors. The metalloid material according to the current disclosure may be deposited in a cross-flow reaction chamber. The metalloid material according to the current disclosure may be deposited in a showerhead reaction chamber.

First precursor is provided in the reaction chamber containing the substrate 204. Without limiting the current disclosure to any specific theory, first precursor may chemisorb on the substrate during providing first precursor into the reaction chamber. The duration of providing first precursor into the reaction chamber (first precursor pulse time) may be, for example, 0.5 seconds, 1 second, 1.5 seconds, 2 seconds, 3 seconds, 4 seconds or 5 seconds.

In the second deposition phase 206 of method 200, a second precursor is provided in the reaction chamber. Without limiting the current disclosure to any specific theory, second precursor may react with the chemisorbed first precursor. The duration of providing the second precursor into the reaction chamber (second precursor pulse time) may be, for example, 0.5 seconds, 1 second, 1.5 seconds, 2 seconds, 2,5 seconds, 3 seconds, 4 seconds or 5 seconds.

Phases of providing a first precursor 204 and providing a second precursor 206 may be performed in any order. The phases of providing a first precursor 204 and providing a second precursor 206 may constitute a sub-cycle, resulting in the deposition of first metalloid material. In some embodiments, the two phases of metalloid material deposition, namely providing the first precursor and the second precursor in the reaction chamber (204 and 206), may be repeated (loop 208). Such embodiments contain several deposition cycles.

In the next step 210, first precursor is provided in the reaction chamber. Without limiting the current disclosure to any specific theory, first precursor may chemisorb on the previously deposited metalloid during providing first precursor into the reaction chamber. The duration of providing first precursor into the reaction chamber (first precursor pulse time) may be, for example, 0.5 seconds, 1 second, 1.5 seconds, 2 seconds, 3 seconds, 4 seconds or 5 seconds.

In the second deposition phase 212 of a method 200, a third precursor is provided in the reaction chamber. Without limiting the current disclosure to any specific theory, third precursor may react with the chemisorbed first precursor. The duration of providing the third precursor into the reaction chamber (third precursor pulse time) may be, for example, 0.5 seconds, 1 second, 1.5 seconds, 2 seconds, 2,5 seconds, 3 seconds, 4 seconds or 5 seconds.

Phases of providing a first precursor 210 and providing a third precursor 212 may be performed in any order. The phases of providing a first precursor 210 and providing a third precursor 210 may constitute a sub-cycle, resulting in the deposition of second metalloid material. In some embodiments, the two phases of metalloid material deposition, namely providing the first precursor and the third precursor in the reaction chamber (210 and 212), may be repeated (loop 214). Such embodiments contain several deposition cycles.

The thickness of the deposited metalloid materials may be regulated by adjusting the number of deposition cycles. The super cycle (loop 216) may be repeated until a desired metalloid material thickness is achieved. For example, about 50, 100, 200,300, 400, 500, 700, 800, 1,000, 1,200, 1,500, 2,000, 2,400 or 3,000 deposition cycles may be performed. The cyclical deposition may result in the formation of a metalloid layer comprising two mutually different metalloids. The layer may be substantially continuous or continuous.

In some embodiments, the cyclic deposition process comprises providing the first precursor and the second precursor, and/or the first precursor and the third precursor, alternately and sequentially in the reaction chamber. In some embodiments, the reaction chamber is purged between precursors, 205, 207, 211, 213, as depicted in FIG. 2B. In such embodiments, a first sub-cycle may be considered to contain phases 204, 205, 206 and 207, and a second sub-cycle may be considered to contain phases 210, 211, 212 and 213. As above, a sub-cycle 108, 214, and super-cycle 216 may be repeated a number of times to achieve desired metalloid material thickness.

First precursor and second precursor may be provided in the reaction chamber in separate steps (204 and 206). FIG. 2B illustrates an embodiment according to the current disclosure, where steps 204 and 206 are separate by purge steps 205 and 207. In such embodiments, a deposition cycle comprises one or more purge steps 203, 205. During purge steps, precursor and/or reactant can be temporally separated from each other by inert gases, such as argon (Ar), nitrogen (N2) or helium (He) and/or a vacuum pressure. The separation of first precursor and second precursor may alternatively be spatial.

First precursor and third precursor may be provided in the reaction chamber in separate steps (210 and 212). FIG. 2B illustrates an embodiment according to the current disclosure, where steps 210 and 212 are separate by purge steps 211 and 213. In such embodiments, a deposition cycle comprises one or more purge steps 211, 213. During purge steps, precursor and/or reactant can be temporally separated from each other by inert gases, such as argon (Ar), nitrogen (N2) or helium (He) and/or a vacuum pressure. The separation of first precursor and second precursor may alternatively be spatial.

Purging the reaction chamber 203, 205, 211, 213 may prevent or mitigate gas-phase reactions between a first precursor and a second precursor, and enable possible self-saturating surface reactions. Surplus chemicals and reaction byproducts, if any, may be removed from the substrate surface, such as by purging the reaction chamber or by moving the substrate, before the substrate is contacted with the next reactive chemical. In some embodiments, however, the substrate may be moved to separately contact a first precursor and a second precursor. Because in some embodiments, the reactions may self-saturate, strict temperature control of the substrates and precise dosage control of the precursors may not be required. However, the substrate temperature is preferably such that an incident gas species does not condense into monolayers or multimonolayers nor thermally decompose on the surface.

When performing the method 200, metalloid material is deposited onto the substrate. The deposition process may be a cyclical deposition process, and may include cyclical CVD, ALD, or a hybrid cyclical CVD/ALD process. For example, in some embodiments, the growth rate of a particular ALD process may be low compared with a CVD process. One approach to increase the growth rate may be that of operating at a higher deposition temperature than that typically employed in an ALD process, resulting in some portion of a chemical vapor deposition process, but still taking advantage of the sequential introduction of a first precursor and a second precursor. Such a process may be referred to as cyclical CVD. In some embodiments, a cyclical CVD process may comprise the introduction of two or more precursors into the reaction chamber, wherein there may be a time period of overlap between the two or more precursors in the reaction chamber resulting in both an ALD component of the deposition and a CVD component of the deposition. This is referred to as a hybrid process.

In accordance with further embodiments, a cyclical deposition process may comprise the continuous flow of one reactant or precursor and the periodic pulsing of the other chemical component into the reaction chamber. The temperature and/or pressure within a reaction chamber during step 204 can be the same or similar to any of the pressures and temperatures noted above in connection with step 206. The temperature and/or pressure within a reaction chamber during step 210 can be the same or similar to any of the pressures and temperatures noted above in connection with step 212.

In some embodiments, the first precursor is brought into contact with a substrate surface 204, excess first precursor is partially or substantially completely removed by an inert gas or vacuum 205, and second precursor is brought into contact with the substrate surface comprising first precursor. First precursor may be brought in to contact with the substrate surface in one or more pulses 204. In other words, pulsing of the first precursor 204 may be repeated. The first precursor on the substrate surface may react with the second precursor to form first metalloid material on the substrate surface. Also, pulsing of the second precursor 206 may be repeated. In some embodiments, second precursor may be provided in the reaction chamber first 206. Thereafter, the reaction chamber may be purged 205 and first precursor provided in the reaction chamber in one or more pulses 204.

In some embodiments, the first precursor is brought into the reaction chamber 210, excess first precursor is partially or substantially completely removed by an inert gas or vacuum 211, and second precursor is brought into contact with the substrate surface comprising first precursor 212. First precursor may be brought in to contact with the substrate surface in one or more pulses 210. In other words, pulsing of the first precursor 210 may be repeated. The first precursor on the substrate surface may react with the second precursor to form second metalloid material on the substrate surface. Also, pulsing of the second precursor 212 may be repeated. In some embodiments, second precursor may be provided in the reaction chamber first 212. Thereafter, the reaction chamber may be purged 211 and first precursor provided in the reaction chamber in one or more pulses 210.

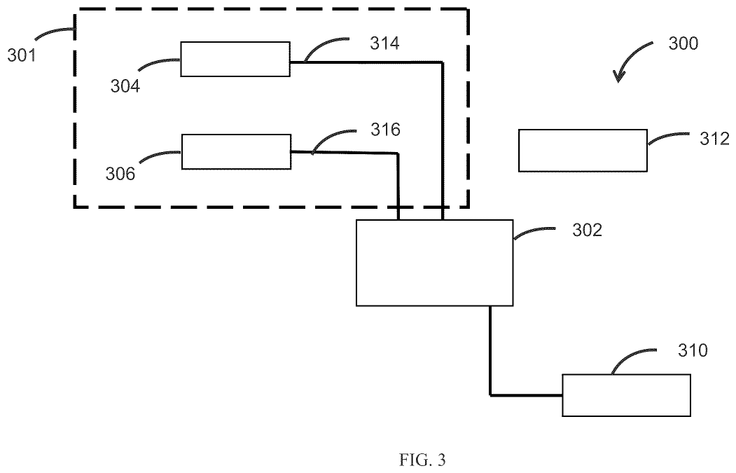

FIG. 3 illustrates a deposition assembly 300 according to the current disclosure in a schematic manner. Deposition assembly 300 can be used to perform a method as described herein and/or to form a structure or a device, or a portion thereof as described herein.

In the illustrated embodiment, deposition assembly 300 includes one or more reaction chambers 302, a precursor injector system 301, a first precursor vessel 304, a second precursor vessel 306, an exhaust source 310, and a controller 312. The deposition assembly 300 may comprise one or more additional gas sources (not shown), such as an inert gas source, a carrier gas source and/or a purge gas source.

Reaction chamber 302 can include any suitable reaction chamber, such as an ALD or CVD reaction chamber as described herein.

The first precursor vessel 304 can include a vessel and one or more first precursors as described herein-alone or mixed with one or more carrier (e.g., inert) gases. A second precursor vessel 306 can include a vessel and a second precursor as described herein-alone or mixed with one or more carrier gases. Although illustrated with two source vessels 304, 306, deposition assembly 300 can include any suitable number of source vessels. Source vessels 304, 306 can be coupled to reaction chamber 302 via lines 314, 316, which can each include flow controllers, valves, heaters, and the like. In some embodiments, the first precursor in the first precursor vessel 304 and the second precursor in the second precursor vessel 306 may be heated. In some embodiments, a vessel is heated so that a precursor or a reactant reaches a temperature between, for example, about 30° C. and about 200° C., depending on the properties of the chemical in question.

Exhaust source 310 can include one or more vacuum pumps.

Controller 312 includes electronic circuitry and software to selectively operate valves, manifolds, heaters, pumps and other components included in the deposition assembly 300. Such circuitry and components operate to introduce precursors, reactants and purge gases from the respective sources. Controller 312 can control timing of gas pulse sequences, temperature of the substrate and/or reaction chamber 302, pressure within the reaction chamber 302, and various other operations to provide proper operation of the deposition assembly 300. Controller 312 can include control software to electrically or pneumatically control valves to control flow of precursors, reactants and purge gases into and out of the reaction chamber 302. Controller 312 can include modules such as a software or hardware component, which performs certain tasks. A module may be configured to reside on the addressable storage medium of the control system and be configured to execute one or more processes.

Other configurations of deposition assembly 300 are possible, including different numbers and kinds of precursor and reactant sources. Further, it will be appreciated that there are many arrangements of valves, conduits, precursor sources, and auxiliary reactant sources that may be used to accomplish the goal of selectively and in coordinated manner feeding gases into reaction chamber 302. Further, as a schematic representation of a deposition assembly, many components have been omitted for simplicity of illustration, and such components may include, for example, various valves, manifolds, purifiers, heaters, containers, vents, and/or bypasses.

During operation of deposition assembly 300, substrates, such as semiconductor wafers (not illustrated), are transferred from, e.g., a substrate handling system to reaction chamber 302. Once substrate(s) are transferred to reaction chamber 302, one or more gases from gas sources, such as precursors, reactants, carrier gases, and/or purge gases, are introduced into reaction chamber 302.

In some embodiments, the first precursor is supplied in pulses, the second precursor is supplied in pulses and the reaction chamber is purged between consecutive pulses of the first precursor and the second precursor.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Various modifications of the disclosure, in addition to those shown and described herein, such as alternative useful combinations of the elements described, may become apparent to those skilled in the art from the description. Such modifications and embodiments are also intended to fall within the scope of the appended claims.

1. A method for depositing metalloid-containing material on a substrate by a cyclic deposition process, the method comprising:
providing a substrate in a reaction chamber;
providing a first precursor into the reaction chamber in vapor phase; and
providing a second precursor into the reaction chamber in vapor phase,
wherein at least one of the first precursor or the second precursor comprise a metalloid compound.

2. The method according to claim 1, wherein the metalloid-containing material is elemental metalloid.

3. The method according to claim 1, wherein the first precursor comprises alkyl silyl or silyl.

4. The method according to claim 1, wherein the first precursor comprises metalloid alkyl silyl or metalloid silyl.

5. The method according to claim 1, wherein the second precursor comprises a halide.

6. The method according to claim 5, wherein the second precursor comprises a metalloid halide.

7. The method according to claim 6, wherein the metalloid of the first precursor or the second precursor is selected form the group consisting of tellurium, germanium, boron, silicon, arsenic, selenium and antimony.

8. The method according to claim 6, wherein the metalloid of the first precursor or the second precursor is tellurium or germanium.

9. The method according to claim 6, wherein the metalloid in the first precursor and the second precursor is tellurium.

10. The method according to claim 6, wherein the metalloid in the first precursor is tellurium and the metalloid in the second precursor is germanium.

11. The method according to claim 1, wherein the first precursor is selected from the group consisting of (Et₃Si)₂Te, Te(SiMe₃)₂, (Me₈SiTe₂, Te(GeMe₃)₂, (Me₃Si)₃Sb, (Et₃Si)₃Sb, (Et₃Si)₃As, (Me₃Si)₂Te, (ⁱPr₃Si)₂Te, (^{t}BuMe₂Si)₂Te, (Et₃Ge)₂Te, (Me₃Ge)₂Te, (ⁱPr₃Ge)₂Te, (^{t}BuMe₂Ge)₂Te, (Me₂Ge)₂Te₂, (Me₂GeC₂H₄GeMe₂)Te, (Me₂GeGeMe2)₂Te₂, Me₈Ge₄Te₂, Te(GeMe₃)₂, (Me₃Ge)₃Sb, (Et₃Ge)₃Sb and Et₃Ge)₃As.

12. The method according to claim 11, wherein the first precursor comprises (R₃Si)₂Te, wherein R is a C1-C4 alkyl.

13. The method according to claim 1, wherein the first precursor comprises a compound selected from the group of general formulas consisting of (R₂Si)₂E₂, (R₂SiC₂R₄SiR₂)E and (R₂SiSiR₂)₂E, wherein E=Te or Se and each R independently selected from C1-C4 alkyls.

14. The method according to claim 13, wherein the first precursor comprises (Et₃Si)₂Te.

15. The method according to claim 1, wherein the second precursor comprises BBr₃, BCl₃, Si₂Cl₆, SiCl₂H₂, Si₂Cl₅H, SiCl₄, SiCl₂Me₂, SiI₄, GeCl₄, Ge(thd)Cl, GeCl₂·dioxane, HGeCl₃, SbCl₃, SbCl₅, AsCl₅, AsCl₂, Se₂Cl₂, SeCl₂, SeCl₄ and TeCl₂.

16. The method according to claim 15, wherein the second precursor comprises TeCl2 or GeCl2·dioxane.

17. A method for deposing metalloid-containing material on a substrate by a cyclic deposition process, the method comprising a super cycle comprising providing a substrate into a reaction chamber and two sub-cycles, the first sub-cycle comprising:
providing a first precursor into the reaction chamber is vapor phase; and
providing a second precursor into the reaction chamber in vapor phase;
the second sub-cycle comprising:
providing a first precursor into the reaction chamber is vapor phase; and
providing a third precursor into the reaction chamber in vapor phase;
wherein the first precursor comprises metalloid alkyl silyl,
wherein the second precursor comprises metalloid halide,
wherein the third precursor comprises metalloid halide, and
wherein the second precursor and the third precursor are mutually different.

18. The method according to claim 17, wherein the first precursor is selected from the group consisting of (Et₃Si)₂Te, (Me₃Si)₂Te, (ⁱPr₃Si)₂Te, (^{t}BuMe₂Si)₂Te, (Me₂Si)₂Te₂, (Me₂SiC₂H₄SiMe₂)Te, (Me₂SiSiMe2)₂Te₂, Me₈Si₄Te₂, Te(GeMe₃)₂, (Me₃Si)₃Sb, (Et₃Si)₃Sb, (Et₃Si)₃As, (Et₃Ge)₂Te, (Me₃Ge)₂Te, (ⁱPr₃Ge)₂Te, (ⁱPr₃Ge)₂Te. (ⁱBuMe₂Ge)₂Te, (Me₂Ge)₂Te₂, (Me₂GeC₂H₂GeMe₂)Te, (Me₂GeGeMe2)₂Te₂, Me₈Ge₄Te₂, (Me₃Ge)₃Sb, (Et₃Ge)₃Sb, and (Et₃Ge)₃As.

19. The method according to claim 17, wherein the second precursor and third precursor are selected from the group consisting of BBr₃, BCl₃, Si₂Cl₆, SiCl₂H₂, Si₂Cl₅H, SiCl₄, SiCl₂Me₂, SiI₄, GeCl₄, Ge(thd)Cl, GeCl₂·dioxane, HGeCl₃, SbCl₃, SbCl₅, AsCl₅, AsCl₅, Se₂Cl₂, SeCl₂, SeCl₄ and TeCl₂.

20. A deposition assembly for depositing metalloid-containing material on a substrate comprising:
one or more reaction chambers constructed and arranged to hold the substrate;
a precursor injector system constructed and arranged to provide a first precursor and a second precursor into the reaction chambe in a vvapor phase, wherein at least one of the first precursor or the second precursor comprise a metalloid compound;
the deposition assembly further comprising a precursor vessel constructed and arranged to contain the first precursor;
the deposition assembly further comprising a precursor vessel constructed and arranged to contain the second precursor,
wherein the assembly is constructed and arranged to provide the first precursor and the second precursor via the precursor injector system to the reaction chamber to deposit the metalloid-containing material on the substrate.
